(19) United States
(12) Patent Application Publication
(10) Pub. No.: US 2004/0194001 A1
(43) Pub. Date: Sep. 30, 2004

(54) CRC checking and error tagging system and method for audio data

(76) Inventors: Yao Ting, Santa Clara, CA (US); Christopher S. Maslyar, San Jose, CA (US); Xuyun Chen, San Jose, CA (US)

Correspondence Address: GRAY CARY WARE & FREIDENRICH LLP, 2000 UNIVERSITY AVENUE, E. PALO ALTO, CA, 94303-2248, US

(21) Appl. No.: 10/743,847

(22) Filed: Dec. 22, 2003

Related U.S. Application Data
(60) Provisional application No. 60/437,488, filed on Dec. 31, 2002.

(51) Int. Cl. H03M 13/00

(52) U.S. Cl. 714/776

(57) ABSTRACT

A method and apparatus for error detection are presented. The method includes looking for a data packet having a predetermined format and enabling an error-checking hardware module upon detecting an input data packet having the predetermined format. The incoming data frames are checked for errors and, if an error is found, an error flag is inserted in the data packet. The flagged data packets are stored in a memory unit with the error flag so that when the data frames are subsequently decoded, the flagged data frames are processed to fix the errors. The error detection apparatus includes a parsing module that looks for data frames having a predetermined format. When such data frames are located, an error-checking module becomes enabled and an error status flag is inserted in the data stream so that the decoder can decode the according to the error status flag.

### RELATED APPLICATION

This application claims the benefit, under 35 U.S.C. § 119(e), of U.S. Provisional Application No. 60/437,488 filed on Dec. 31, 2002.

### BACKGROUND OF THE INVENTION

This invention relates generally to a system and method for decoding audio data that has cyclic redundancy check (CRC) and in particular to a system and method for efficiently decoding the CRC codes in audio data.

Today, data is stored on various types of optical media so that the data may be played back. For video data, one popular format for the optical media is the digital video disk (DVD) format. In general, program streams from DVD discs have video and audio packets intermixed in an endless stream. The initial MPEG decoding process typically involves de-multiplexing the different elements of the program stream (such as the audio stream, the video stream, etc.), and parsing the video, audio, sub-picture, etc. elements that are of interest. Then, the parsed elements are stored in separate buffers (video in a video buffer, audio in audio buffer, etc.) according to their purpose for subsequent decoding. For AC-3 formatted audio data, which is most widely used in DVD playback, an error detection mechanism is employed before actual decoding begins. This error detection mechanism is the well known cyclic redundancy check (CRC) coding which detects if errors exist in the audio data.

Currently, the CRC error detection mechanism is typically implemented in a software that checks the CRC codes during audio processing. However, the current CRC error detection has limitations. For example, since the CRC codes are decoded and checked when the audio processing of the audio data has already begun, the audio processing is slowed down or even stopped to handle an error if there is one. Furthermore, since the software CRC detection method uses look-up tables to reduce processing time, it necessitates a lot of storage space. Although fast software CRC methods are available, these methods tend to deal with data at the byte level, whereas audio decoding requires that the data be dealt with at the bit level. Therefore, these fast CRC methods are not appropriate for audio decoding.

In light of the above limitations with the currently available CRC error detection mechanisms, a way of checking CRC error in audio data at a fast speed without using a lot of memory is needed.

### SUMMARY OF THE INVENTION

Program streams from DVD discs include video and audio packets intermixed in an endless stream. The initial MPEG decoding process typically involves demultiplexing the different elements of the program stream, selecting only the video, audio, sub-picture, . . . elements that are of interest. The parsed elements are stored in separate buffers (video in video, audio in audio, . . . ) according to their purpose for subsequent decoding. An audio processor retrieves data from an audio buffer, performs the decoding algorithm, and outputs decoded audio samples in an output buffer. For AC-3 formatted audio data, which is most widely used in DVD playback, an error detection mechanism is employed before actual decoding begins. The invention provides a novel architecture for performing CRC checking and error tagging of AC-3 frame data during the demultiplexing process.

For AC3 audio format, which is most widely used in DVD playback, an error correction mechanism based on CRC calculations is required before the real decoding starts. The invention provides a method for using a dedicated CRC hardware module on the data path to do CRC calculation before sending data to the audio buffer. The method of the invention uses a system CPU to check an incoming data stream, perform frame analyzing, and control the transfer of audio data to the CRC hardware module, which inserts error flags into the bit streams according to CRC error status. The AC3 decoder will do the error correction according to the embedded error flag in the input data so that no software CRC calculation is needed and the processor cycles (MIPs) to support error correction for AC3 decoding is minimized.

A method of detecting an error in a data stream is presented. The method includes parsing input data packets while looking for a data packet having a predetermined format and enabling an error-checking hardware module upon detecting an input data packet having the predetermined format. In more detail, the method includes checking incoming data frames for errors, inserting an error flag where there is an error, storing the data frames in a memory unit after inserting the error flag, and decoding the data frames by reading the data from the memory unit and processing the flagged data frame differently from flag-less data frames. Also presented is an apparatus for error detection in a data stream, wherein the apparatus includes a parser unit for parsing the data stream and looking for data frames having a predetermined format, an error-checking module that becomes enabled if the parser unit finds data frames having the predetermined format, wherein the error-checking module inserts an error status flag in the data stream upon finding an error, and a decoder for decoding the data according to the error status flag.

Although the invention is described in the context of AC3 audio format, the invention can support CRC calculation for other audio formats.

### BRIEF DESCRIPTION OF THE DRAWINGS

FIG. 1 is a diagram illustrating an example of product, such as a DVD player, that may include the audio error checking system in accordance with the invention;

FIG. 2 is a diagram illustrating more details of the MPEG decoder that may include the audio error checking system in accordance with the invention;

FIG. 3A is a diagram illustrating an MPEG video and audio decoding process using the hardware shown in FIGS. 1 and 2;

FIG. 3B is a diagram illustrating an MPEG audio decoding process using the hardware shown in FIGS. 1 and 2;

FIG. 4A is a diagram illustrating an audio data error checking system in accordance with the invention that may be implemented on the hardware shown in FIGS. 1 and 2;

FIG. 4B is a block diagram of a generalized CRC computation module used in audio decoding; and

FIG. 5 is a flowchart illustrating an audio data error checking method in accordance with the invention.

### DETAILED DESCRIPTION OF A PREFERRED EMBODIMENT

The invention is particularly applicable to AC-3 audio data and DVD disks and it is in this context that the invention will be described. It will be appreciated, however, that the audio data error checking system and method in accordance with the invention has greater utility since the system and method may be used with other types of audio data or other types of data that include audio data with error codes and may also be used with other types of media which store audio and/or video data and may be used with audio and video data that is received over a computer network, streamed or received over a wireless network, etc.

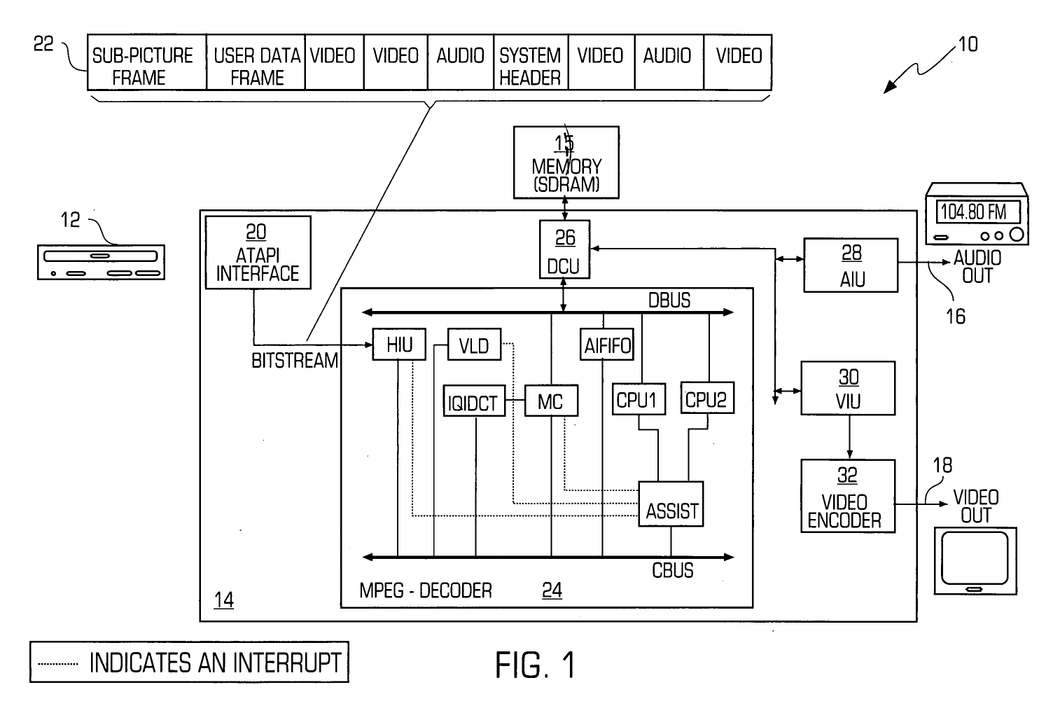

FIG. 1 is a diagram illustrating an example of product 10, such as a DVD player, that may include the audio error checking system in accordance with the invention. The product 10 may include an input receptacle 12 for a piece of media, such as a DVD disk, a decoder unit 14 and memory 15, such as SDRAM. The digital encoded data may also be downloaded to the product, for example over a computer network or a wireless network. The product may receive digital data from the disk inserted into the input receptacle and may output an audio output stream 16 and a video output stream 18 as is well known. The decoder unit 14 may be one or more semiconductor chips and circuitry. The decoder unit may also include one or more pieces of software, software modules or firmware that are stored in the memory 15. The combination of the hardware circuitry and the firmware/software are used to implement the well known digital data decoding process.

In more detail, the decoder unit 14 may include an advanced technology attachment packet interface (ATAPI) 20 which receives the digital encoded data (a bitstream 22) from the media. The bitstream may include interleaved frames of data as shown in FIG. 1, such as a sub-picture frame, a user data frame, one or more video frames, one or more audio frames and a system header frame which are all well known. The bitstream 22 may be fed into an MPEG decoder 24 as shown. The decoder unit 14 may further comprise a DRAM control unit (DCU) 26 that is a module that is responsible for SDRAM control and buffer management, an audio interface unit (AIU) 28, a video interface unit (VIU) 30 and a video encoder 32. The audio interface unit is responsible for distributing the decoded audio data including both analog and digital data wherein the analog data may, for example, comply with the I²S standard and the digital data may comply, for example, with the IEC958 standard. The video interface unit is responsible for mixing and filtering the digital video data before the digital data is sent to the video encoder 32. The video interface may include a variety of different video converting methods, such as NTSC to PAL, PAL to NTSC, pan-scan to letterbox, letterbox to pan-scan, etc . . . . In operation, the product shown receives the digital data from a piece of media and outputs data streams which correspond to audio data as well as video data. Now, the MPEG decoder 24 will be described in more detail.

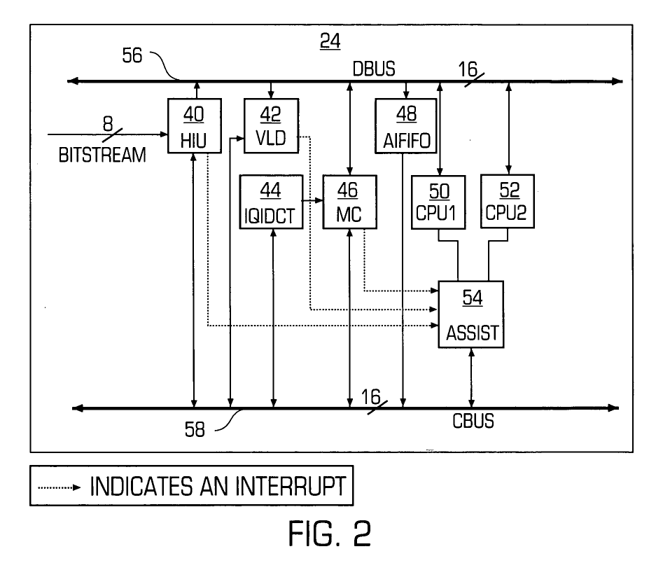

FIG. 2 is a diagram illustrating more details of the MPEG decoder 24 that may include the audio error checking system in accordance with the invention. The MPEG decoder may comprise a host interface unit (HIU) 40, a variable length decoder (VLD) 42, an inverse quantization and inverse discrete cosine transform unit (IQIDCT) 44, a motion compensation unit (MC) 46, an audio interface FIFO (AFIFO) 48, a first central processing unit (CPU1) 50, a second central processing unit (CPU2) 52 and an assistant unit (ASSIST) 54 which are connected together by a data bus (DBUS) 56 and a control bus (CBUS) 58. In addition, the elements are interconnected together as shown in FIG. 2. For example, the HIU, VLD and MC may generate interrupts which are fed into the ASSIST unit 54 as shown.

The host interface unit (HIU) 40 is responsible for decrypting and de-multiplexing the MPEG-2 audio/video bitstream. For DVD applications, the input bitstream is often encrypted by CSS (Content Scrambling System) requiring real-time decryption in some cases. The HIU may also convert the 8-bit incoming bitstream to 16-bit data in order to store the de-multiplexed data into the 16-bit SDRAM 15 as shown in FIG. 1. The variable length decoder (VLD) 42 is responsible for parsing the MPEG-2 video bitstream and decoding the variable length code. The VLD 42 supports all forms of MPEG-1 and MPEG-2 variable length code tables. The motion vectors are also decoded by the VLD 42. The VLD may operate in one of three modes: slave mode, startcode mode, and decoding mode. In slave mode, CPU1 50 performs bit by bit shifts and parses the video data from VLD input buffer using a special instruction. In the startcode mode, VLD will search for a startcode and will generate an interrupt to CPU1 when a startcode is found. In the decoding mode, VLD decodes macroblocks of the video bitstream one by one.

The IQIDCT unit 44 is responsible for the calculation of inverse quantization, arithmetic, saturation, mismatch control, and 2-dimensional (2D) 8×8 inverse discrete cosine transform as are well known. In general, there are two ways to implement a 2D IDCT. One method uses row-column decomposition, while the other uses a 2D direct implementation. We have implemented the row-column decomposition method because it yields a relatively small area in a chip. The motion compensation unit (MC) 46 receives data from the IQIDCT 44 and is responsible for reading reference pictures from SDRAM, performing horizontal and vertical interpolation, and writing the reconstructed pixels into SDRAM. All of the prediction modes for MPEG-2 such as frame-based, field-based, dual prime type and so on are supported.

Both CPU1 50 and CPU2 52 are nearly identical in their instruction sets and architecture (e.g., pipelining, interrupt handling, use of local and program memory) with the exception that CPU2 incorporates several DSP functions not found in CPU1. Both CPUs have their own local memory and DMA engine that is used to transfer block data between SDRAM and local memory. CPU1 is mainly responsible for assisting in video decoding and display control while CPU2 is dedicated for audio decoding. The ASSIST unit 54 is responsible for CBUS read/write arbitration and interrupt routing between the hardware modules and to the two CPUs. The interrupts from the hardware modules can be programmatically mapped to either or both CPUs which increases the decoders flexibility. The AIFIFO 48 obtains block data from SDRAM and outputs the data bit by bit according to setting of control registers. CPU1 or CPU2 can read bit data from this AIFIFO module through CBUS. This function assists in audio decoding by reducing the CPU load demand.

As illustrated in FIG. 2, there are two main buses in the diagram: CBUS 58 and DBUS 56. CBUS is a simple 16-bit control bus through which all control or parameter data is passed. CBUS transactions take two cycles to access a control register. Both the CPUs can access the CBUS through CBUS arbitration logic in the ASSIST module. DBUS 56 is designed to carry block data that is transferred between an external SDRAM and internal hardware modules. As illustrated in FIG. 2, every module connected to the DBUS carries a buffer, typically 64×16 FIFO, to store the data sent to or from the external SDRAM. These buffers exist to increase the memory bandwidth efficiency when data is being transferred to or from the external SDRAM. Now, the audio decoding process using the hardware shown in FIG. 2 will be described.

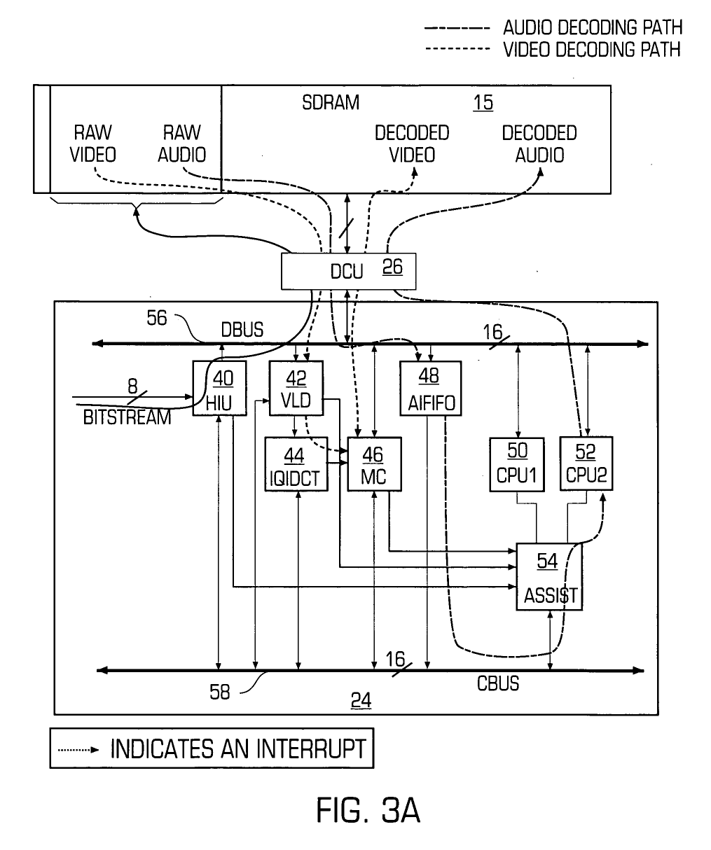

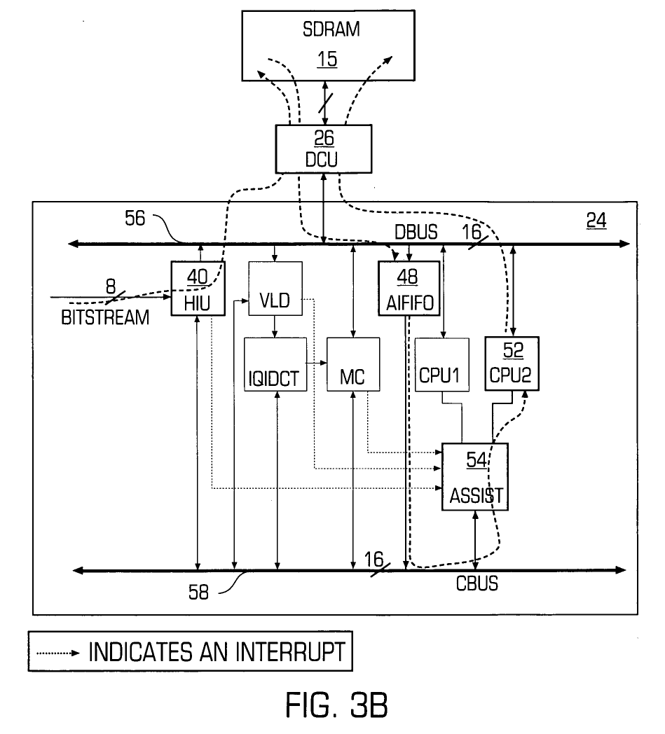

FIG. 3A is a diagram illustrating an MPEG video and audio decoding process using the hardware shown in FIGS. 1 and 2. In the embodiment that is shown, the SDRAM 15 includes at least four blocks: a block for undecoded video data (RAW Video), a block for undecoded audio data (RAW Audio), a block for decoded video data, and a block for decoded audio data. As described above, the HIU 40 decrypts the input bitstream, determines whether the data is audio or video, and stores the data in the appropriate block of the SDRAM 15. Then, the HIU 40, the VLD 42, the IQIDCT 44, the MC 46, the CPU1 60, and the ASSIST 54 cooperate to decode video data in the input bitstream and the decoded video data is stored in the “decoded video” block of the SDRAM 15. As for the audio data, the AIFIFO 48, the CPU2 52, and the ASSIST 54 cooperate to decode the audio data and the decoded audio data is stored in the “decoded audio” block of the SDRAM 15.

FIG. 3B is a diagram illustrating an MPEG audio decoding process using the hardware shown in FIGS. 1 and 2. In particular, those modules being used during the audio decoding process are shown normally while the modules which do not participate in the audio processing are shown grayed out. In operation, as bitstream data flows into the HIU's input FIFO, CPU1 reads the input FIFO (over the CBUS) to determine the type of data being sent to the HIU. If CPU1 finds audio data in the bitstream, it instructs the HIU to redirect subsequent audio data to a raw data audio buffer established in the external SDRAM. After HIU finishes transferring data to SDRAM, it will generate an interrupt to CPU1 and wait for CPU1 to issue new command. Once the AIFIFO module determines that there is data in the raw data audio buffer established in the external SDRAM, AIFIFO begins reading that data. Using the CBUS to communicate with the AIFIFO, CPU2 reads the raw audio data from AIFIFO, decodes it, and places the uncompressed decoded audio data back into the external SDRAM into one of two new buffer locations in the external SDRAM. There are two destination buffers for uncompressed-decoded audio data that is placed in the external SDRAM. One is called the I2S buffer. This buffer is allocated for uncompressed-decoded data suitable for analog output. The other buffer is called the IEC958 buffer. This buffer is used to hold data that will eventually be sent out through the IEC958 digital output. Depending on the format of audio data, these two buffers may or may not share the same SDRAM space. CPU2 is used to control the flow of uncompressed-decoded audio data. When CPU2 determines that there is sufficient uncompressed-decoded audio data in the I2S buffer, it configures the AIU module to begin reading and processing I2S buffer data. Once the AIU has processed a block of I2S data, it interrupts CPU2 to indicate it has completed its task. The same procedure applies to the IEC958 buffer. First CPU2 determines if the IEC958 buffer has data. If so, CPU2 configures the AIU to process IEC958 data. Once the AIU has completed a block of IEC958 data, it interrupts CPU2 to indicate it is done. Now, the audio data error checking system and method in accordance with the invention will be described.

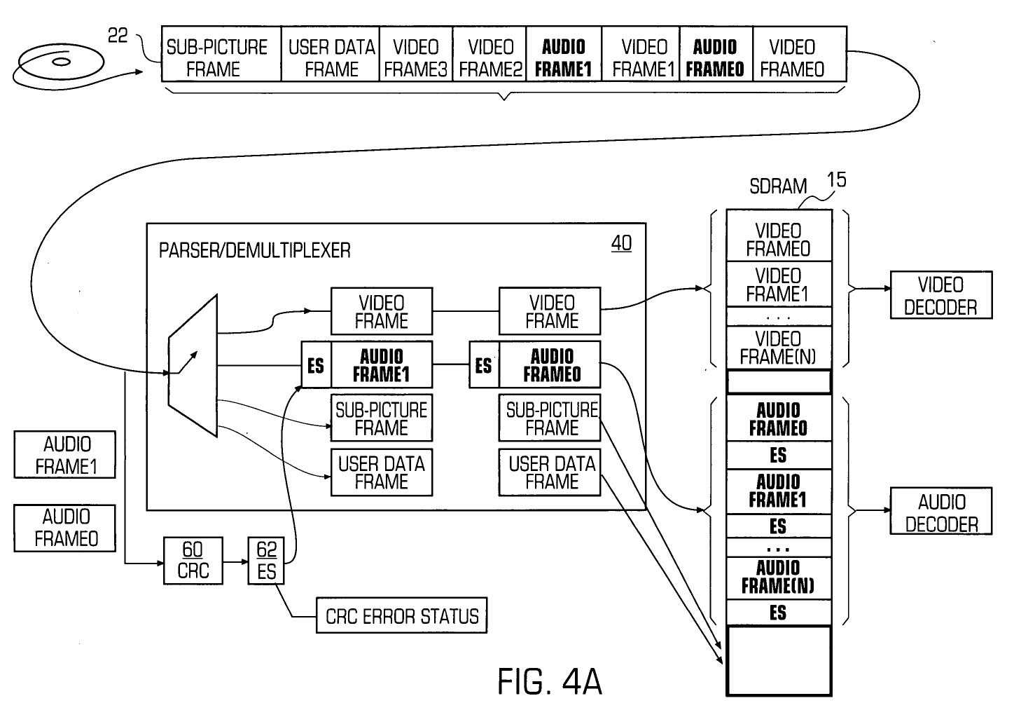

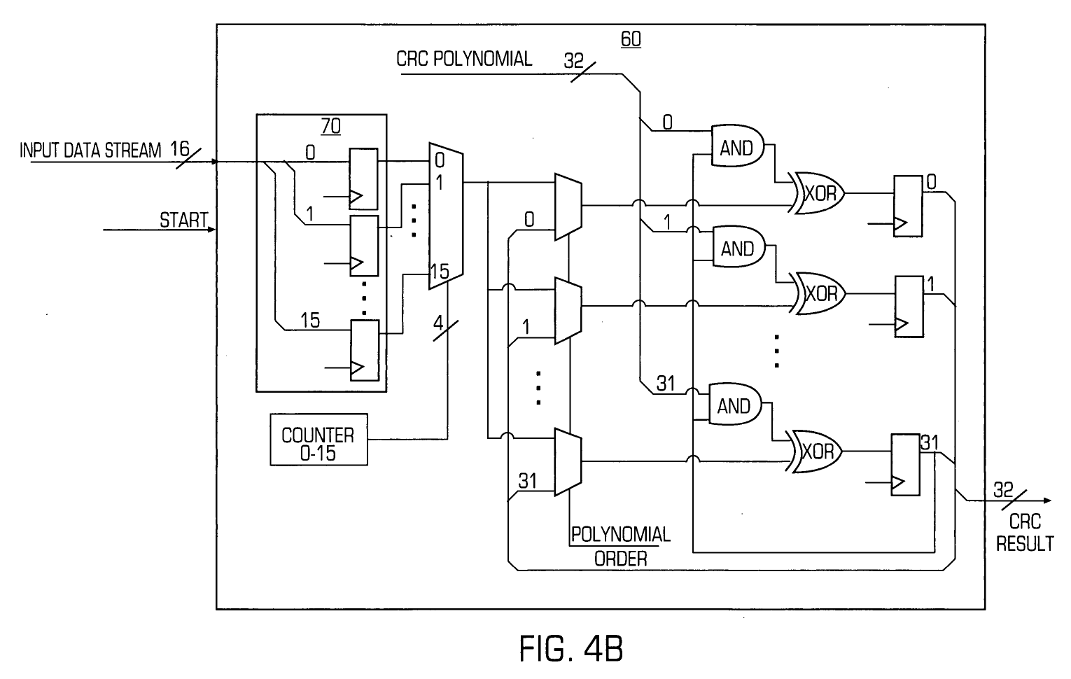

FIG. 4A is a diagram illustrating an audio data error checking system in accordance with the invention that may be implemented on the hardware shown in FIGS. 1 and 2. As illustrated in FIG. 4A, the data 22 originating from a DVD disc is comprised of stream of intermixed data packets or frames. The mix may contain video, audio, sub-picture and user data and often includes different variations of each type of data. For example, the stream may include audio frames in English as well as audio frames in another language or sub-picture data and video may contain a mix of English and Chinese sub-titles.

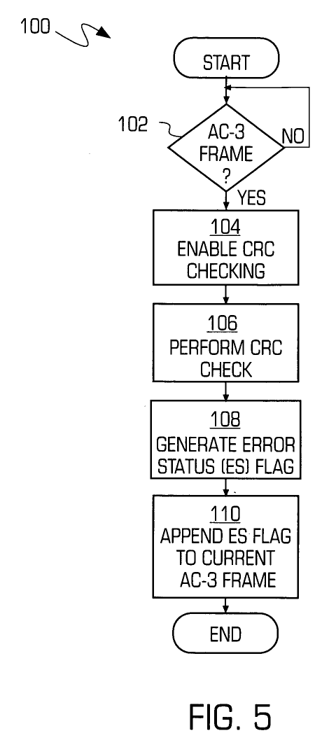

The first step in the decoding process involves parsing the stream to extract only those packets that are of interest (e.g. only those suitable for an English language presentation in this example). When the parser encounters a frame of interest, it redirects that frame to the appropriate buffer allocated in an SDRAM. There are four different buffers allocated in the SDRAM corresponding to the four frame types being parsed: video, audio, sub-picture and user data. This separation into different buffers is called demultiplexing as is performed by the Host Interface Unit 40 as shown in FIG. 4A. All frames are handled identically in that they are first identified by the parser as frames of interest before they are stored in a pre-defined buffer in an SDRAM according to their type. Frames are identified by header information that precedes the data associated with the frame as is well known. In the case of AC-3 type audio data there is one small variation to the storage process. In addition to a header and data, AC-3 frames have a Cyclic Redundancy Check (CRC) associated with each frame. This Cyclic Redundancy Check must be computed before the decoding process is applied to the AC-3 data. Although it's possible to perform the Cyclic Redundancy Check on the AC-3 frame data after all data have been placed into buffer memory, this invention takes an alternative approach. Thus, in step 102 (see FIG. 5), the CRC error checking method determines if there is an AC-3 frame and continues to loop until an AC-3 frame has been found.

FIG. 4B is a block diagram of a generalized CRC module 60 used in audio decoding. As indicated in FIG. 4A, a CRC hardware module 60 sits in parallel with the parser and sees the same data stream as the parser. The CRC module 60 includes an array of flip-flops 70, a selector 72 coupled to a counter 74, and a gate array 80. The bytes or words of the input data stream are divided into bits (in this example, 16 bits) and held in the array of flip-flops 70 that create a one-clock-cycle delay. The selector 72 selects one bit at a time, preferably in the order of arrival, and forwards the selected bit to the gate array 80 which performs polynomial division. In this case, the polynomial division is performed using mainly AND gates and exclusive OR gates, as shown. However, a person of ordinary skill in the art will understand that the CRC module shown in FIG. 4B is an exemplary CRC module, and there are other ways to achieve polynomial division at a binary level. The process is repeated for each byte or word until the entire byte or word is decoded.

FIG. 5 is a flowchart illustrating an audio data error checking method 100 in accordance with the invention. Whenever the parser encounters an AC-3 frame of interest, the parser enables the CRC hardware module in step 104. Once enabled, the CRC hardware module performs a well known Cyclic Redundancy Check in step 106 on the AC-3 data at the same time that the data is sent to the buffer in SDRAM by the parser. Once the entire AC-3 frame has been checked (the CRC module knows the length of the frame), the CRC module 60 generates an Error Status byte 62 in step 108. This Error Status byte generated by the CRC module 60 is appended to end of the associated AC-3 frame that was just placed into the SDRAM buffer by the parser in step 110 as shown in FIG. 4A. In this manner, the AC-3 audio data is error checked in parallel with the parsing process. As shown, the audio data with the appended error status byte leave the parser and are stored in the SDRAM 15 so that a well known audio decoder may decode the audio data with the CRC error checking completed.

The advantages of using hardware (the CRC module 60) to pre-compute and tag the encoded AC-3 data before it is placed into buffer memory are twofold. First, computing the CRC in hardware alleviates the need for a high-speed CPU to perform the audio decoding since some portion of that decoding process is now being handled by the CRC module 60. In addition, since the data is pre-tagged with an error status, the audio processor has sufficient time to compensate for the bad audio frame(s) since the audio processor knows that an audio frame is bad when it starts the decoding process. With a typical system in which an audio processor performs the CRC error check during the decoding process, the audio processor will not know that it has a bad audio frame until it completes the CRC check.

As described above, the pre-computation of the CRC values reduces the burden on the audio decoder. A purely software based CRC calculation is inefficient for several reasons. The CRC checking mechanism is widely used and there are many CRC calculation methods. Many fast CRC methods perform the CRC calculation in bytes or word units and these parallel algorithms use look-up tables to minimize calculation time at the expense of additional storage. Although appropriate for many applications, byte or word unit CRC computations are not applicable to audio decoding CRC computations since audio decoding requires the ability to deal with the data at the bit level so that bit level CRC computations are required. Therefore, the fast software CRC methods cannot be used.

One method to work around the problem is to create an internal bit cache to get the data in units of 16 bits or 8 bits, do the CRC calculation and use a sub-routine to return the required bits to data requestor. However, this method may affect the decoding speeds because every time you need data, you have to make a call and use some registers to transfer parameters, which may make the code size large and inefficient. This technique also may require a large CRC look-up table in ROM. Another choice is to do CRC calculation bit by bit. However, the bit by bit CRC calculation will greatly increase the processing load of the audio process which is often not acceptable.

Using a typical software-based CRC decoding method in which the CRC checksum is determined first and then the audio decoding occurs later, the method needs to either have a way to reload audio data from outside or make the local memory (on chip RAM/SRAM/high speed RAM) large enough to contain one frame. This results in a large memory within the audio processor which increases the cost of the system. In addition, using the typical software method, if you want to perform CRC checking and audio decoding at the same time and hope the decoding can be interrupted when a wrong CRC checksum is found, that will be a little dangerous because the decoder may crash before the arrival of wrong CRC signal.

Unlike the typical software solutions which have the above problems, including having to fetch data twice (once for CRC calculation and once for audio decoding), a CRC hardware method as described above avoids that problem since it performs the CRC check before the decoding. One method of hardware CRC calculation is to get data from memory and then send the CRC check signals to the audio decoder. However, then a mechanism to keep the synchronization between the hardware and software decoder is needed, which makes things complex. In this invention, both disadvantages of the methods can be avoided by adding the CRC module on the data path, which receives data from outside world. Further, no synchronization is needed between the hardware and software decoder, which make it possible to minimize the memory and MIPs requirement of the decoder.

While the foregoing has been with reference to a particular embodiment of the invention, it will be appreciated by those skilled in the art that changes in this embodiment may be made without departing from the principles and spirit of the invention, the scope of which is defined by the appended claims.

What is claimed is:

1. A method of detecting an error in a data stream, the method comprising:
parsing input data packets while looking for a data packet having a predetermined format; and
enabling an error-checking hardware module upon detecting an input data packet having the predetermined format.

2. The method of claim 1, wherein the error-checking hardware module inserts an error status flag into a data packet if an error is detected.

3. The method of claim 2 further comprising decoding the data packets according to the inserted error status flags.

4. The method of claim 1 further comprising selecting audio data from the input data packets and storing the audio data in a designated storage location.

5. The method of claim 1, wherein the predetermined format is AC-3 format and the error-checking hardware module is configured to perform cyclic redundancy check.

6. The method of claim 1, wherein the error-checking hardware module is configured to perform cyclic redundancy check at bit level.

7. The method of claim 6, wherein the cyclic redundancy check comprises:
creating at least a one-cycle delay; and
subjecting each bit of the data packets to polynomial division.

8. The method of claim 1, wherein the input data packets comprise one or more of a sub-picture frame, a user data frame, a video frame, and an audio frame.

9. The method of claim 1 further comprising decrypting and demultiplexing the input data packets.

10. A method of checking errors in a data stream, the method comprising:
checking data frames for errors;
inserting an error flag into each data frame to create a flagged data frame upon detecting an error;
storing each flagged data frame in a memory unit; and
decoding each flagged data frame by reading the data from the memory unit and processing the flagged data frame based on the error flag.

11. The method of claim 10 further comprising checking for data frames having AC-3 format before checking for errors.

12. The method of claim 10 further comprising detecting an error in the data frame using polynomial division.

13. The method of claim 10 further comprising performing cyclic redundancy check on each bit of data.

14. A method of decoding a data stream, the method comprising:
flagging errors in a data stream to generate a flagged data frame; and
decoding a data frame by processing the flagged data frame differently from data frames that do not contain an error.

15. An apparatus for detecting an error in a data stream, the apparatus comprising:
a parser unit for parsing the data stream to identify a data frame having a predetermined format;
an error-checking module that becomes enabled if the parser unit identifies a data frame having the predetermined format, wherein the error-checking module inserts an error status flag in the data frame upon finding an error; and
a decoder for decoding the data stream according to the error status flag.

16. The apparatus of claim 15 further comprising:
an interface module that demultiplexes the data frames; and
a memory control module that is coupled to the interface module and the decoder to store raw and decoded data.

17. The apparatus of claim 16 further comprising a first bus and a second bus connected to the decoder, wherein the first bus is a control bus for transmitting control and parameter data to a control register and the second bus is configured to transmit data between the memory control module, the interface module, and the parser unit.

18. The apparatus of claim 16 further comprising a first processor and a second processor, wherein the first processor is programmed to decode audio data and the second processor is programmed to decode video data.

19. The apparatus of claim 18 further comprising hardware modules configured to perform video decoding, the hardware modules communicating with the second processor to decode video data while the decoder is decoding audio data.

20. The apparatus of claim 16 further comprising a memory unit that stores data frames with error status flags and makes the data frames accessible to the error-checking module.

21. The apparatus of claim 15, wherein the parser unit and the error-checking module are connected in parallel and receive the same data.

22. The apparatus of claim 15, wherein the predetermined format is AC-3 audio format.

23. The apparatus of claim 15, wherein the error-checking module comprises:
an array of flip-flops to retain bits of data and create a delay;
a selector coupled to the array for sequentially selecting one bit;
a counter coupled to the selector to determine the number of bits operated on; and
a gate array configured to perform polynomial division on each sequential bit of data.
